(19) United States
(12) Patent Application Publication
(10) Pub. No.: US 2015/0351258 A1
(43) Pub. Date: Dec. 3, 2015

(54) Method for Producing a Multilayer Carrier Body

(71) Applicant: EPCOS AG, München (DE)

(72) Inventors: Thomas Feichtinger, Graz (AT); Axel Pecina, St. Martin (AT); Stefan Obermair, Stainz (AT); Werner Tschnuchnig, Soboth (AT)

(73) Assignee: EPCOS AG, München (DE)

(21) Appl. No.: 14/654,436

(22) PCT Filed: Nov. 26, 2013
(86) PCT No.: PCT/EP2013/074771

§ 371 Date: Jun. 19, 2015

(30) Foreign Application Priority Data
Dec. 21, 2012 (DE) 10 2012 113 018.3

(51) Int. Cl. H05K 3/46; B32B 37/06; B32B 15/04; B32B 37/10

(52) U.S. Cl. CPC H05K 3/4611; B32B 37/10; B32B 37/06; B32B 15/04; B32B 2305/80; B32B 2457/08; B32B 2457/14

(57) ABSTRACT

A method for producing a multilayer carrier body is disclosed. A method for producing a multilayer carrier body. The method includes producing films by printing a first area of each film with a first paste and printing a second area of the film with a second paste. The method also includes stacking the films and laminating the films.

This patent application is a national phase filing under section 371 of PCT/EP2013/074771, filed Nov. 26, 2013, which claims the priority of German patent application 10 2012 113 018.3, filed Dec. 21, 2012, each of which is incorporated herein by reference in its entirety.

### TECHNICAL FIELD

Embodiments of the invention provide a method for producing a multilayer carrier body.

### BACKGROUND

In LTCC and HTCC processes (LTCC, Low Temperature Cofired Ceramics; HTCC, High Temperature Cofired Ceramics), films structured by laser or stamping methods are created to form a feedthrough. In this way, structures for 2.5D technology can be produced. The basic material for constructing an LTCC or HTCC ceramic wafer may be films of, for example, a glass ceramic in the thickness range of 50-150 μm. This technology is not suitable for thinner layer-to-layer spacings of below 10 μm for the construction of very thin panels.

The feedthroughs created by lasering in the LTCC/HTCC process have a diameter in the range of 20-100 μm. Feedthroughs created by stamping have a diameter in the range of 50-300 μm. For larger openings, of a diameter greater than 500 μm, LTCC/HTCC technology tends to be unsuitable. Such openings are required unfilled for the formation of cavities or metal-filled for thermal purposes, for example, as a heat sink in a high-power LED carrier.

The production of a multilayer component by means of multiple printing steps on a substrate is described in European Patent Publication No. 2381451.

### SUMMARY

The method for producing a multilayer carrier body comprises: producing films by printing a first area with a first paste and printing a second area with a second paste, stacking the films and laminating.

By printing the first and the second area within the contour of a film, a film is produced for a film stack. A film is a thin sheet formed by printed areas of the dried first paste and second paste. It comprises the printed first area and second area, the thickness of which corresponds to the thickness of the film. A third area may be printed with a third paste. Further printing steps for printing further areas with further pastes may be provided. The printing takes place in the form of applying the pastes to a carrier, from which the dried pastes are detached as a film. Multiple films are printed simultaneously and bonded together as a web, so that, at the time of stacking, the films for multiple stacks are combined as a web and they are individually separated in a later step.

With this method, multilayer carrier bodies with structures formed in any way desired in the carrier substrate can be produced by stacking films of which the structures correspond to sections through the desired multilayer carrier body. Thus, for example, multilayer ceramic bodies with an integrated heat sink can be produced for 2.5D and 3D technology.

The printing may take place by a screenprinting process or an inkjet printing process. The screenprinting process is a multiple screenprinting process, in which the areas are printed one after the other with different pastes. The layer thickness may be smaller than 20 μm and lie in the range of 10 μm.

This process is suitable for structures of a large surface area. The inkjet process, in which small droplets of paste are applied to the carrier impact-freely, is suitable for fine structures, known as fine-line structures.

Usually, one of the areas is printed first. After the drying of the paste, the printing of the other area takes place. When laminating, heat acts on the films to achieve an intimate bond between the paste structures of the areas.

A paste of the first paste and the second paste is a ceramic paste, and the other paste is a paste with metallic constituents. The latter is used for printing onto the areas that form feedthroughs or integrated heat sinks. Polymer pastes may also be used.

Further production steps apart from the printing and drying of the first paste, for example, a ceramic paste, and the printing and drying of the second paste, for example, a metal paste, as well as further printing steps with further pastes, are the stacking of the films and the laminating. During the laminating, the stacked films are intimately bonded. In the same step or in a separate, preceding laminating step, the different pastes may be intimately bonded to one another in a film plane at the interfaces. Further production steps are the pressing, in which pressure can be applied to the film stack during the laminating operation, the decarburizing of the pressed film stack and also the sintering. Optionally, an insulating layer may be subsequently sputtered on, in order to achieve an electrical insulation of the integrated heat sink. Furthermore, a conductor structure may be applied, for example, taking the form of an interposer. Such a conductor structure may be printed on. A reflective layer may, for example, be applied by printing. Such a reflective layer may be provided in the case of LED carriers. Such surface structuring processes comprise, for example, metallization processes such as sputtering and photolithographic processes.

It is also possible to connect the stack built up from the multiply printed films to a further film stack or one or more other films, for example, for insulation purposes or for increasing the mechanical strength. This may take place, for example, by laminating. Such a further film stack may be a ceramic film stack produced by LTCC/HTCC technology.

The multiple paste layer process described makes it possible to produce 2.5D and 3D multilayer wafer structures from ceramics, metals and polymers with very thin layer-to-layer spacings, smaller than 20 μm, and complex structures of feedthroughs and cavities.

Cavities and hollow spaces can form by free areas on the films being left unprinted when films are stacked one on top of the other. The bottom or top of the cavities and hollow spaces are formed by films printed in this region.

The areas may have separate subareas that are printed with the same paste. The films may be printed in such a way that, in a sectional plane, a subarea of the first area surrounds the second area or a subarea thereof in which for its part there is a subarea of the first area. Alternatively, it may be provided that, in a sectional plane, the first area or a subarea thereof surrounds the second area or a subarea thereof in which for its part there is a free area or a third area. The sectional plane runs along a film layer of the multilayer carrier body. Consequently, nested structures, in which one structure has further structures or cavities provided inside it, can form in the multilayer carrier body.

Stacked films with the same area contours can be used to form structures with an unchanged cross section along the vertical axis of the multilayer carrier body, that is to say the perpendicular to the layers. The stacked films may, however, also be designed in such a way that the contours of the areas of films lying one on top of the other are differently formed. In this way structures of which the cross section changes along the vertical axis can be formed. First areas of one film and second areas of a neighboring film may overlap, or the first area of one film or of multiple films may lie at least partially between second areas of neighboring films thereover and thereunder, so that a region of the structure that protrudes into the other material is formed.

The three-dimensional structure in the multilayer carrier body is created by the structures lying one on top of the other, that is to say areas of the same paste, of the stacked films. Perpendicular lateral surfaces parallel to the vertical axis of the three-dimensional structure are created by films stacked one on top of the other in which the contours, that is to say peripheries of the areas, match. Curved lateral surfaces of the three-dimensional structure are created by films in which the contours deviate slightly from one another from layer to layer in such a way that, when stacked one on top of the other, they produce the curved lateral profile. Edges in the lateral surround can be achieved by the contour of a region of the structure deviating significantly from the contour lying thereunder, so that the area reaching beyond the contour lying thereunder forms the underside of a region of the structure that has an edge at the limit of the layer. This edge consequently runs perpendicularly to the vertical axis.

The multilayer carrier body may have a substrate, in which there is a structured functional region, that is to say a structure, the substrate extending both to the sides of and also at least partially above and below the functional region and/or the substrate extending both to the sides of and entirely above and/or below the functional region and/or the substrate or a further region being arranged in the functional region or protruding into it.

### BRIEF DESCRIPTION OF THE DRAWINGS

The invention is explained below on the basis of exemplary embodiments with reference to the drawing, in which:

FIG. 1 shows a plan view of an exemplary embodiment of a multilayer carrier body and a section through it;

FIG. 2 shows a plan view of a further exemplary embodiment of a multilayer carrier body;

FIG. 3 shows a plan view of a further exemplary embodiment of a multilayer carrier body and a section through it;

FIG. 4 shows a plan view of a further exemplary embodiment of a multilayer carrier body and a section through it;

FIGS. 5 to 7 show steps of the production process on the basis of intermediate products; and

FIGS. 8 to 10 show sections through a further exemplary embodiment of a multilayer carrier body.

### DETAILED DESCRIPTION OF ILLUSTRATIVE EMBODIMENTS

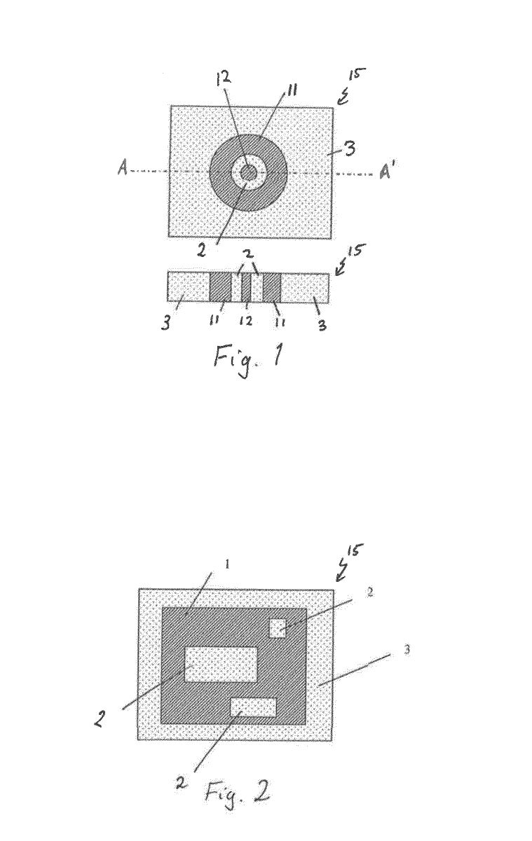

FIG. 1 shows a plan view (at the top) of an exemplary embodiment of a multilayer carrier body and a section (at the bottom) through it along the line A-A′.

The multilayer carrier body 15 has a substrate 3, which surrounds a hollow-cylindrical structure 11, that is to say a region, with an annular cross section. Within this structure 11 there is a further cylindrical structure 12 with a circular cross section, there being a hollow-cylindrical substrate region 2 between the structures 11 and 12, which may be metal. The substrate regions 3, 2 may be of the same or different ceramic materials. The structures 11, 12, 2 have perpendicular lateral surfaces.

The multilayer carrier body 15 is made up of a multiplicity of identical films, the areas of which have been printed, as can be seen in the plan view. If the same material is used for the substrate regions 3, 2, the subareas of the first area 3, 2 are printed with the same ceramic paste. After the drying, the subareas 11, 12 of the second area are printed with a different paste, which, for example, comprises metal components.

In an alternative exemplary embodiment, the hollow-cylindrical region 2 is formed from a material that differs from that of the other regions. In this case, the corresponding area 2 is printed with a third paste in a further step.

The stacking of such identical films with identical contours produces a multilayer carrier body 15, in which the lateral surfaces of the structures that are produced by the contours lying one on top of the other run parallel to the vertical axis of the carrier body, that is to say perpendicularly to the layers.

Such nested structures, and also the structures that follow, cannot be produced by standard LTCC/HTCC processes.

FIG. 2 shows a plan view of a further exemplary embodiment of a multilayer carrier body.

The description concentrates on the differences from the previous exemplary embodiment.

In this exemplary embodiment, a structure 1, for example, a metal structure, with a rectangular outer contour is surrounded by a ceramic substrate 3 of a first material. Provided in this structure 1 are three rectangular structures 2 with a rectangular cross section, passing right through the multilayer carrier body 15, of a further ceramic material, which differs from the outer substrate 3. These cuboidal structures 2 may alternatively be of the same material as the outer-lying substrate 1 or of a number of materials that are different from one another.

The multilayer carrier body 15 is made up of a multiplicity of identical films, the areas of which are printed as can be seen in the plan view. The outer-lying first area 3 has been printed with a ceramic paste. After that, the second area 1, lying therein, has been printed with a metal paste. If the rectangles 2 lying in the second area 1 are printed with the same paste as the outer-lying area 3, they can be printed in the same step. Otherwise, their printing takes place in one or more further steps with a further paste or further pastes.

The stacking of such identical films with identical contours produces a multilayer carrier body 15 in which the lateral surfaces of the structures 1, 2 that are produced by the contours lying one on top of the other run parallel to the vertical axis of the carrier body, that is to say perpendicularly to the film layers.

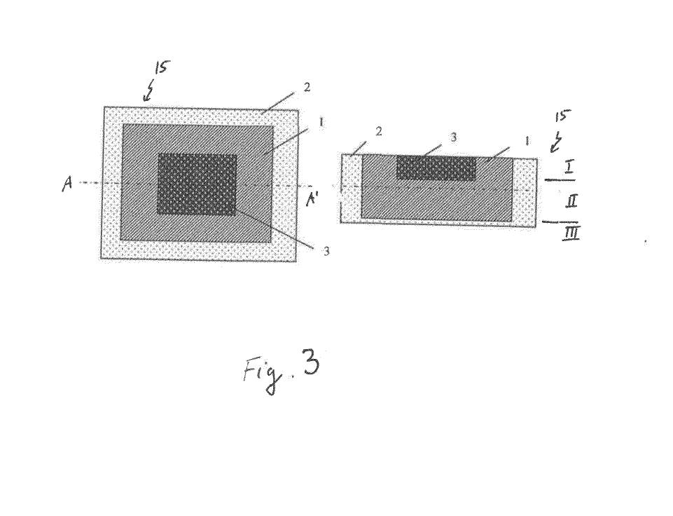

FIG. 3 shows a plan view (on the left) of a further exemplary embodiment of a multilayer carrier body and a section (on the right) through it along the line A-A′.

In this exemplary embodiment, a well-like metallic structure 1 is surrounded at the side surfaces and at the bottom by a ceramic substrate 2. Provided in the structure 1 is a further, cuboidal structure 3 of a further material, for example, a different ceramic material.

This multilayer carrier body 15 is made up of three different types of film. In the upper region I, the area arrangement thereof corresponds to the plan view. The rectangular third area 3 is surrounded by the frame-like second and first areas 1, 2. In the region II lying thereunder, the films have a second area 1 without an inner contour. The second area 1 is rectangular. In the lower region III, the films have been printed over the entire surface area with the paste for the first area 2.

FIG. 4 shows a plan view (on the left) of a further exemplary embodiment of a multilayer carrier body and a section (on the right) through it along the line A-A′.

In this exemplary embodiment, a well-like metallic structure 1 is surrounded at the side surfaces and at the bottom by a ceramic substrate 21. Provided in the structure 1 is a further well-like structure 22 of the ceramic material of the outer well 21, in which there is a cuboidal cavity 4.

This multilayer carrier body 15 is made up in the upper region I of stacked films, the areas 4, 22, 1, 21 of which have been printed in the way represented in the plan view. The cavity 4 is formed by a free area 4, that is to say an unprinted clearance in the film. In the region II lying thereunder, the films differ from those in the upper region I in that the inner-lying subarea 22 no longer has a free region, but is rectangular. Its outer contour is unchanged. In the region III lying thereunder, the films differ from those in the region II in that the metal area 1 is rectangular. Its outer contour is unchanged. In the region IV lying thereunder, the films have been printed over the entire surface area with the paste for the first area 21. Neighboring films, in which various areas lie one on top of the other, form the horizontal interfaces between the well-like structures 21, 1, 22.

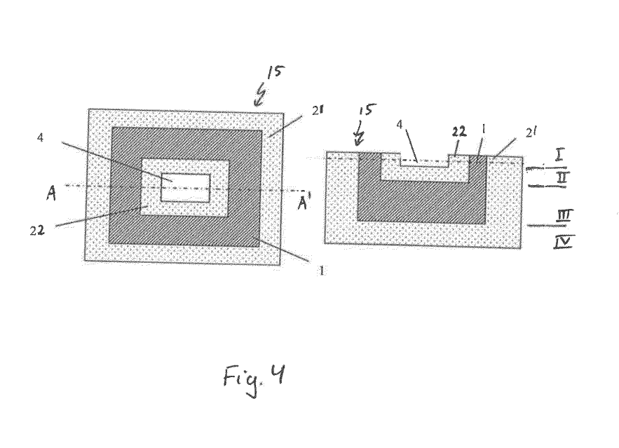

FIGS. 5-7 illustrate the exemplary production of a multiple layer carrier body on the basis of intermediate products.

Firstly, in one step, the first areas 2 for a multiplicity of films 10 that are initially still combined in a web are printed onto a carrier or a carrier film 25. After the drying of the ceramic paste, the second areas 11, 12, which comprise three subareas 11, 12, are printed on the carrier 25 with a metal paste, which likewise dries.

FIG. 5 shows a web with a multiplicity of ready-printed films 10 with first and second areas 2, 11, 12. The enlargement of a cutout shows the films 10 of this web in detail.

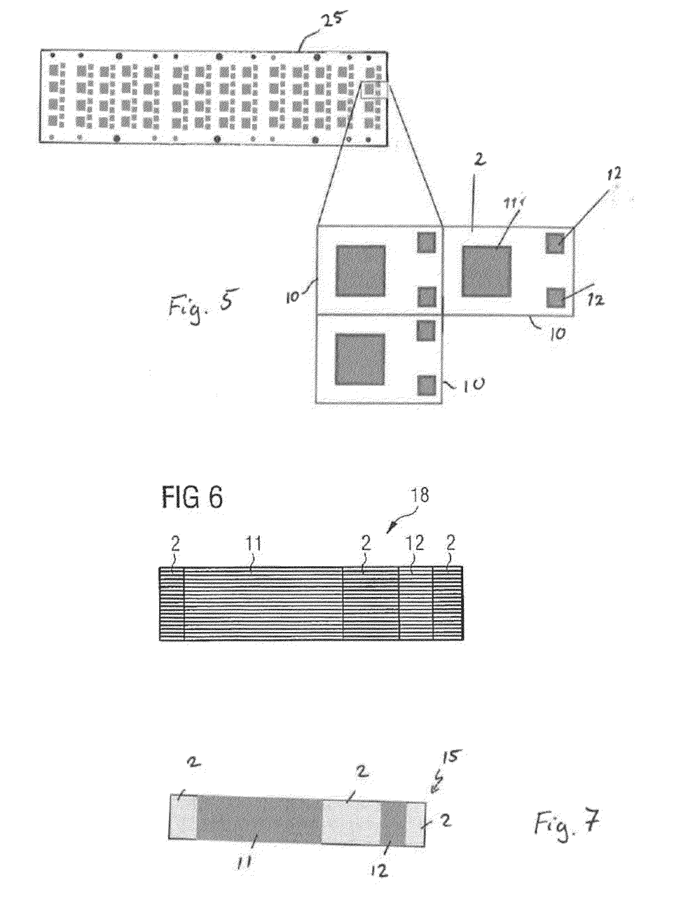

Subsequently, the paste structures are laminated. During the laminating, stacking and pressing of the film webs, they are laid one on top of the other to form stacks and are intimately bonded to one another under the action of heat and pressure. FIG. 6 shows such a stack 18 after laminating and pressing.

During the subsequent decarburizing and sintering, organic constituents are thermally removed and the layers are firmly bonded to form the multilayer carrier body 15. FIG. 7 shows such a multilayer carrier body 15 after the decarburizing and sintering.

Optionally, further layers and structures may be applied to the multilayer carrier body 15, in order to make it into a component carrier. Further steps may, for example, comprise sputtering an insulating layer. The multilayer carrier body 15 may be printed with a conductor structure, for example, an interposer. Optionally, a reflective layer may be printed on, in order to use the multilayer carrier body 15, for example, as an LED carrier.

Furthermore, separation of the stack to form the individual multilayer carrier bodies 15 is required. This may be a step that follows the surface structuring.

Apart from the method described above for producing a multilayer paste construction, a mixed construction comprising multilayer paste films and conventional films is also conceivable. The method for its production differs from the above in that, after the laminating of the paste films, laminating of the paste stack with the conventionally produced film stack is also provided. This is likewise followed by pressing, decarburizing and sintering as well as surface structuring processes, as described above.

By this method, a multilayer carrier body is produced from stacked printed films that have areas printed with different pastes. The sequence of the method step may vary.

In this way, for example, a 2.5D or 3D multilayer structure can be produced.

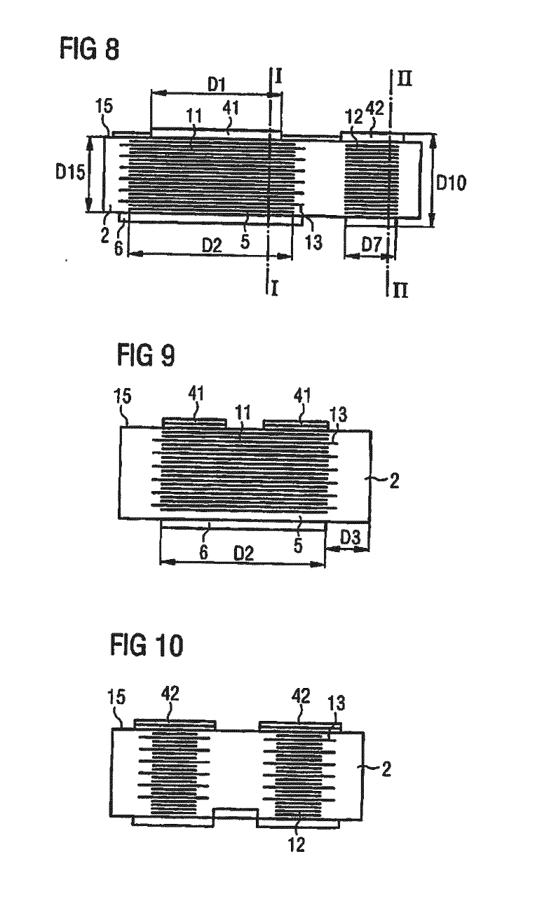

FIG. 8 shows a section through the exemplary embodiment of the multilayer carrier body that has been produced by the production method described. FIG. 9 shows a section through the exemplary embodiment of the multilayer carrier body along the line I-I. FIG. 10 shows a section through the exemplary embodiment of the multilayer carrier body along the line II-II.

The multilayer carrier body 15 serves as an LED carrier, on which an LED, as a component with a strong heat build-up, and also a further component can be mounted. For this purpose, solder pads 41, 42, on which the components (not represented) can be fixed, are provided on the upper side of the carrier body 15.

This exemplary embodiment comprises three structured functional regions 11, 12. One structure, which is a first functional region 11, extends underneath the solder pads 41 for the LED and runs from the upper side of the multilayer carrier body 15 to an insulating layer 5 on the underside of the multilayer carrier body. This insulating layer 5 may be of the same material as the substrate 2 surrounding the first functional region 11. This functional region 11, serving as a heat sink, has a cylindrical, in this case cuboidal, main body. Protruding into the substrate 2 from the perpendicular lateral surface of the main body are horizontally running regions 13, which are formed as structured layers. These structured layers may be respectively produced from one or more film layers. These regions 13 protruding into the substrate 2 may be a cross-sectional enlargement of the main body, the contour of which is at an equal distance from the contour of the main body. They may alternatively take the form of strips or webs. Because of their form, they may also be referred to as an electrode structure. They improve the mechanical adaptation between metal and ceramic at the transition from the substrate 2 to the functional region 11, in that, for example, material stresses are avoided.

Mounted on the underside of the multilayer carrier body 15 is a terminal 6.

The multilayer carrier body 15 also has a second and a third functional region 11, which run from the upper side of the multilayer carrier body 15 to the underside thereof.

These functional regions 11 are cylindrical with a rectangular cross section. They may serve as a feedthrough or integrated heat sinks for a further component (not represented).

The width D1 of a solder pad 41 for the LED corresponds to the width of the LED to be mounted thereon and may, for example, be 1000 μm. The width D7 for the further component corresponds to the width thereof and may be 300 μm.

Such a carrier body 15 with surface structures may have a thickness D10 of 500 μm, the substrate 2 having a thickness D15 of 400 μm.

In the substrate 2, the first functional region 11, which serves as a thermal block or heat sink for the LED, and two further functional regions 12 are arranged. Arranged on the underside of the carrier body 15 are terminals 6. The width D2 of the main body of the integrated heat sink, both in the longitudinal direction and in the transverse direction, is 1500 μm. The distance D3 from the periphery of the carrier body is 700 μm (see FIG. 9). The width of the further functional regions 12 corresponds to that of the further component 7 and is 300 μm.

The carrier body 15 has a layered construction and comprises a multiplicity of films 10 that have been printed from pastes and stacked and laminated, in order to form the carrier body 15. The substrate 2 is formed by ceramic layers and the structures 11, 12 lying therein are formed by metal layers, which, for example, comprise copper. In this way it is possible to produce any desired structures within the substrate 2. Thus, for example, the regions 22 protruding from the main body of the functional region can be produced in a simple way, by the metal area of such a layer protruding beyond the layer lying thereunder.

FIG. 9 and FIG. 10 show two further sections through the component along the lines I-I and II-II in FIG. 8. FIG. 9 shows the section I-I, in which it can be clearly seen that the LED is contacted by means of two contacts 41. In the section II-II, it can be seen that the same also applies to the further component. Moreover, it can be seen that horizontally running regions 13, which are formed as structured layers, though only in one main direction, also protrude from the main bodies of the second and third functional regions 12 into the substrate 2. From the main body of the first functional region 11, horizontally running regions 13 protrude into the substrate 2 in the longitudinal direction and the transverse direction, as can be seen in FIGS. 9 and 10.

The features of the exemplary embodiments may be combined.

1-14. (canceled)

15. A method for producing a multilayer carrier body, the method comprising:
producing films by printing a first area of each film with a first paste and printing a second area of the film with a second paste;
stacking the films; and
laminating the films.

16. The method according to claim 15, wherein the printing comprises a screenprinting process.

17. The method according to claim 15, wherein the printing comprises an inkjet printing process.

18. The method according to claim 15, wherein the first area and the second area of one of the films at least partially border one another or overlap only slightly.

19. The method according to claim 15, wherein at least one of the films is printed in such a way that at least one of the first and second areas comprises subareas that are separate from one another.

20. The method according to claim 15, wherein a free area in at least one of the films remains unprinted.

21. The method according to claim 15, wherein a third area is printed with a third paste.

22. The method according to claim 15, wherein the films are printed in such a way that a subarea of the first area surrounds the second area or a subarea thereof in which for its part there is a subarea of the first area.

23. The method according to claim 15, wherein the films are printed in such a way that the first area or a subarea thereof surrounds the second area or a subarea thereof in which for its part there is a free area or a third area.

24. The method according to claim 15, wherein the films are stacked one on top of another in such a way that contours of the areas of neighboring films are formed differently.

25. The method according to claim 15, wherein the films are stacked in such a way that the first area of one film and the second area of a neighboring film overlap.

26. The method according to claim 15, wherein the films are stacked in such a way that the first area of one film or of multiple films lying one on top of the other lies at least partially between second areas of neighboring films.

27. The method according to claim 15, wherein the films are stacked in such a way that the second area of one film or of multiple films lying one on top of the other at least partially lies between first areas of neighboring films.

28. The method according to claim 15, wherein the first paste is a ceramic paste and the second paste is a paste with metallic constituents.

29. The method according to claim 15, further comprising laminating the film stack with a further film stack or a further film.

30. The method according to claim 15, wherein at the time of stacking, films for multiple stacks are connected as a web, the method further comprising individually separating the multiple stacks after the laminating step.

31. The method according to claim 15, further comprising:
pressing the film stack;
decarburizing the film stack; and
sintering the film stack.

32. A multilayer carrier body comprising stacked printed films that have areas printed with different pastes.

33. The multilayer carrier body according to claim 32, wherein the different pastes comprise a ceramic paste and a paste with metallic constituents.
